(19) United States
(12) Patent Application Publication
(10) Pub. No.: US 2025/0349663 A1
(43) Pub. Date: Nov. 13, 2025

(54) HEAT SPREADER STRUCTURE

(71) Applicant: Taiwan Semiconductor Manufacturing Company, Ltd., Hsinchu (TW)

(72) Inventors: Chien-Chang WANG, Hsinchu City (TW); Kuan-Min WANG, Hsinchu City (TW); Ching WANG, Taichung City (TW); Kuo-Chin CHANG, Chiayi City (TW); Kathy Wei YAN, Hsinchu (TW); Jun HE, Zhubei City (TW)

(73) Assignee: Taiwan Semiconductor Manufacturing Company, Ltd., Hsinchu (TW)

(21) Appl. No.: 18/662,384

(22) Filed: May 13, 2024

(51) Int. Cl. H01L 23/373; H01L 23/367; H01L 23/40

(52) U.S. Cl. CPC H01L 23/3736; H01L 23/367; H01L 2023/4068

(57) ABSTRACT

The present disclosure is directed to a structure of a semiconductor package with a heat spreader structure and a method of forming the structure. The method includes providing a substrate with first and second dies on the substrate, dispensing a first thermal interface material (TIM) on the first die, and mounting a heat spreader structure on the first and second dies. A porous metal of the heat spreader structure can be aligned between the first and second dies. The method further includes forming a first thermal contact between the first die and the heat spreader structure via the first TIM, injecting a second TIM on the second die through a perforated hole in the heat spreader structure, and forming a second thermal contact between the second die and the heat spreader structure via the second TIM.

### BACKGROUND

In applications of advanced electronic circuits, multiple integrated circuit (IC) dies (e.g., system on a chip (SoC) dies and memory dies) can be integrated on the same substrate to form an IC package. In the design of IC packages, heat dissipation is an important issue, as the performance of the IC dies can be impacted by the heat they generate.

### BRIEF DESCRIPTION OF THE DRAWINGS

Aspects of the present disclosure are best understood from the following detailed description when read with the accompanying figures.

FIG. 1A is a side view of a structure of semiconductor package including a heat spreader structure, in accordance with some embodiments.

FIG. 1B is a bottom view of a heat spreader structure, in accordance with some embodiments.

FIGS. 2A-2F are patterns of groove structures of a heat spreader structure, in accordance with some embodiments.

FIG. 3 is a flowchart of a method for forming a structure of semiconductor package with a heat spreader structure, in accordance with some embodiments.

FIGS. 4 through 8 are side views of intermediate structures of a semiconductor package with a heat spreader structure during its manufacturing process, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed that are between the first and second features such that the first and second features are not in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the terms “about” and “substantially” can indicate a value of a given quantity that varies within 5% of the value (e.g., +1%, +2%, +3%, +4%, +5% of the value). These values are merely examples and are not intended to be limiting. It is to be understood that the terms “about” and “substantially” can refer to a percentage of the values as interpreted by those skilled in relevant art(s) in light of the teachings herein.

In semiconductor electronic devices, multiple integrated circuit (IC) dies with different specified functions can be mounted on the same substrate to form an IC package. For example, a system on a chip (SoC) die responsible for processing data and one or more memory dies responsible for data storage can be mounted on a substrate, with the one or more memory dies surrounding the SoC die. In this structure, heat generated by the IC dies can be transmitted to a heat spreader structure mounted on the IC dies and dissipated. The thermal conduction between the IC dies and the heat spreader structure can be facilitated by thermal interface materials (TIMs) in contact with top surfaces of the IC dies and a bottom surface of the heat spreader structure. In order to optimize the performances of different IC dies according to their specific characteristics and functionalities, different options of TIMs may be chosen, requiring different treatments to create reliable physical joints between the IC dies and the heat spreader structure. For example, a metal TIM can be applied on the top surface of the SoC die and further treated in a reflow process, whereas a memory TIM can be applied on the top surfaces of the memory dies and further treated in a cure process. Compared with the memory TIM, the metal TIM applied on the SoC die may have a higher thermal conductivity to effectively dissipate a greater amount of heat generated by processors on the SoC die, and can contain metal elements. The SoC die may be arranged to be surrounded by multiple memory dies, and the metal TIM may be applied prior to the memory TIM.

In some cases, the different procedures of treating different TIMs can interfere with each other and compromise the TIMs' performance of thermal conduction. For example, once the metal TIM and the memory TIM are applied, the reflow process to treat the metal TIM can cause the metal TIM to shrink and reduce its coverage on the SoC die, due to the presence of the memory TIM on the adjacent memory die. This is because, compared to the metal TIM, the memory TIM has a harder property and may prevent the heat spreader structure from sinking according to a deformation of the metal TIM during the reflow process, such that a surface tension drives the metal TIM to shrink due to a capillary effect at the narrow gap between the bottom surface of the heat spreader structure and the top surface of the SoC die. In some cases, after the reflow process, bubbles and discontinuities can be formed in the metal TIM, and the coverage of the metal TIM on the SoC die can be reduced by about 30%. In particular, the reduced coverage of the metal TIM on the SoC die can significantly impact areas around corners of the top surface of the SoC die, which can be quantified by a corner thermal resistivity R_{jc}. In some cases, after the reflow process, R_{jc} can increase by a factor of about 2.

To overcome the challenges mentioned above, the embodiments described herein are directed to a method of forming a structure of a semiconductor package with a heat spreader structure for heat dissipation. In some embodiments, a metal TIM can be dispensed on a top surface of an SoC die. Prior to applying a memory TIM on a memory die, the heat spreader structure can be mounted on the metal TIM, with a porous metal on the heat spreader structure aligned with the SoC die and a perforated hole in the heat spreader structure aligned above the memory die. A reflow treatment can then be performed to treat the metal TIM, and a flux vapor released by the metal TIM during the reflow treatment can be exhausted through the perforated hole. The memory TIM can then be injected through the perforated channel and dispensed on the memory die, followed by performing a cure treatment. In some embodiments, during the reflow process, shrinking of the metal TIM can be avoided due to the absence of the memory TIM, and the metal TIM can maintain sufficient coverage over the top surface of the SoC die. In some embodiments, during the reflow process, the flux vapor released by the metal TIM can penetrate through the porous metal and be exhausted by the perforated hole, avoiding its condensation and contamination on internal surfaces within the structure. In some embodiments, during the reflow process, the porous metal can effectively absorb any overflow of the metal TIM over the edge of the SoC die, guarding the metal TIM within the range of the top surface of the SoC die and avoiding its contamination to other parts of the structure.

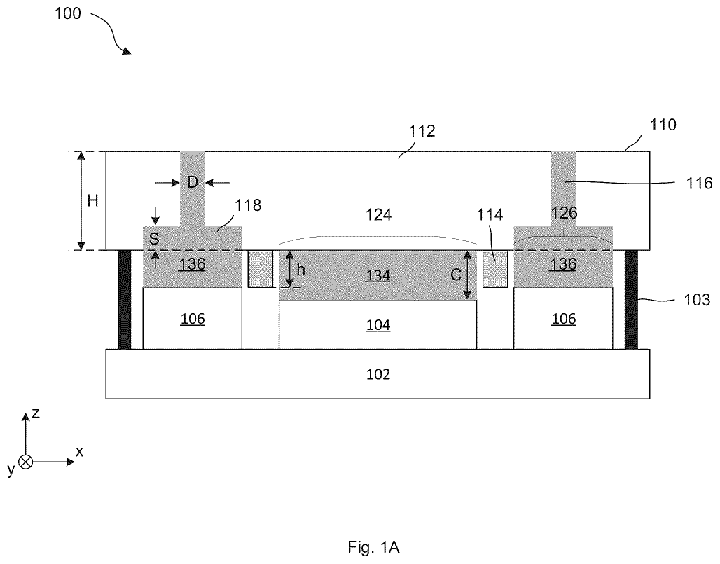

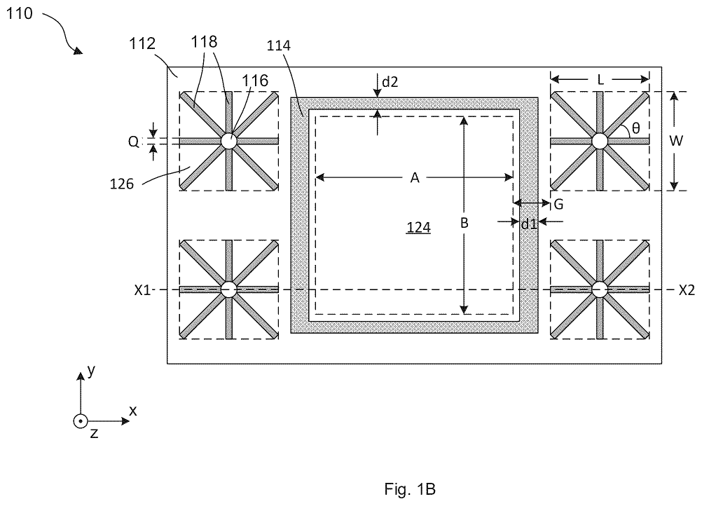

FIG. 1A illustrates a side view of a structure of a semiconductor package having a heat spreader structure, according to some embodiments. FIG. 1B illustrates a bottom view of the heat spreader structure, according to some embodiments. Referring to FIG. 1A, a structure 100 can include a substrate 102. Substrate 102 can extend along horizontal directions (e.g., x and/or y axes) and having a top surface perpendicular to a vertical direction (e.g., a z-axis). Substrate 102 can include a semiconductor material, such as silicon (Si). In some embodiments, substrate 102 can include a crystalline silicon substrate (e.g., Si wafer). In some embodiments, substrate 102 can include (i) an elementary semiconductor, such as silicon or germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Further, substrate 102 can be doped depending on design requirements (e.g., p-type substrate or n-type substrate). In some embodiments, substrate 102 can be undoped. In some embodiments, substrate 102 can be doped with p-type dopants (e.g., boron (B), indium (In), aluminum (Al), or gallium (Ga)) or n-type dopants (e.g., phosphorus (P), arsenic (As), or antimony (Sb)). In some embodiments, a crystal orientation of substrate 102 can be (100), (110), or (111).

Structure 100 can include a number of IC dies that specialized on different functions. For example, as shown in FIG. 1A, structure 100 can include a first IC die (e.g., an SoC die 104) and one or more second IC dies (e.g., memory dies 106) near and/or surrounding the first IC die. Structure 100 can further include a heat spreader structure 110 mounted on the IC dies providing heat dissipation for the IC dies. Structure 100 can also include supporting structures 103 disposed on substrate 102 and supporting edges of heat spreader structure 110. Heat spreader structure 110 can have a thickness H that measures between top and bottom surfaces of heat spreader structure 110. Structure 100 can further include a number of TIMs disposed between heat spreader structure 110 and the IC dies to transfer the heat generated by the IC dies to heat spreader structure 110. In some embodiments, considering different properties and functionalities of the IC dies (e.g., the amount of heat generated by the IC dies and the characteristics of top surfaces of the IC dies), different types of TIMs can be disposed on the IC dies, according to a design requirement. For example, as shown in FIG. 1A, a first TIM (e.g., metal TIM 134) can be disposed on a top surface of SoC die 104 to form a thermal contact between heat spreader structure 110 and SoC die 104, and one or more second TIMs (e.g., memory TIM 136) can be disposed on top surfaces of memory dies 106 to form thermal contacts between heat spreader structure 110 and memory dies 106. Metal TIM 134 and memory TIMs 136 require different treatments to form reliable physical joint between their corresponding IC dies and heat spreader structure 110. For example, metal TIM 134 can be treated in a reflow process, whereas memory TIM 136 can be a treated in a cure process. As shown in FIG. 1A, metal TIM 134 can have a thickness C. In some embodiments, thickness C can be below about 120 μm. For example, thickness C can be about 97 μm. In some embodiments, metal TIM 134 can cover an entirety or almost the entirety of the top surface of SoC die 104. For example, a coverage of metal TIM 134 over the top surface of SoC die 104 can be greater than about 90%. In another example, the coverage of metal TIM 134 over the top surface of SoC die 104 can be about 99.8%. In some embodiments, a corner thermal resistivity R_{jc} of metal TIM 134 can be less than about 0.3° C./W. For example, the corner thermal resistivity R_{jc} of metal TIM 134 can be about 0.24° C./W.

In some embodiments, the bottom surface of heat spreader structure 110 can include different regions, each aligning with one of the top surfaces of the IC dies. Referring to FIG. 1A, heat spreader structure 110 can include a first type region 124 aligned with the top surface of the first IC die, such as SoC die 104. In some embodiments, first type region 124 can be disposed at a central area of the bottom surface of heat spreader structure 110, as shown in FIG. 1B. In some embodiments, first type region 124 and the top surface of SoC die 104 can have a rectangular shape with a width A and a length B. In some embodiments, first type region 124 and the top surface of SoC die 104 can have a square shape with width A and length B being substantially the same. Heat spreader structure 110 can also include one or more second type regions 126 aligned with top surfaces of the second IC dies, such as memory dies 106 as shown in FIG. 1A. In some embodiments, second type regions 126 can be disposed near and/or surrounding first type region 124, as shown in FIG. 1B. First type region 124 and each of the second type regions 126 can be separated by a distance G. In some embodiments, second type regions 126 and the top surfaces of memory dies 106 can have a rectangular shape with a width L and a length W. In some embodiments, second type region 126 and the top surfaces of memory dies 106 can have a square shape with width L and length W being substantially the same.

In some embodiments, as shown in FIG. 1A, heat spreader structure 110 can include perforated channels 116 aligned over memory TIMs 136. Through perforated channels 116, memory TIMs 136 can be injected on the top surfaces of memory dies 106, after the reflow treatment of metal TIM 134. In some embodiments, during the reflow treatment, perforated channels 116 can facilitate a flux vapor released by metal TIM 134 to pass through and to be exhausted. In some embodiments, perforated channels 116 can be partially or entirely filled with memory TIMs 136. Each perforated channel 116 can extend through heat spreader structure 110, with a first port disposed at a top surface of heat spreader structure 110 and a second port disposed at the bottom surface of heat spreader structure 110. The second port can be disposed in one of the second type regions 126. For example, as shown in FIG. 1B, each of the second ports of the perforated channels 116 is disposed around a center of each of second type regions 126. In some embodiments, each of perforated channels 116 can have a round shape cross section, as shown in FIG. 1B. In some embodiments, the cross section of perforated channel 116 can be other shapes, such as a triangular shape, a rectangular shape, a hexagonal shape, an elliptical shape, or an irregular shape. In some embodiments, inner sidewalls of perforated channel 116 can be perpendicular to the top surface of heat spreader structure 110, such that perforated channel 116 can have a cylindrical shape, as shown in FIG. 1A. In some embodiments, inner sidewalls of perforated channels 116 can be tilted with respect to the vertical direction (the z-axis). For example, perforated channel 116 can have a tapered shape, such that the first and second ports can be of different widths. Each of perforated channels 116 can have a width D, as shown in FIG. 1A. In some embodiments, a ratio of width D to length L of second type region 126 can be less than about 0.1. In some embodiments, a ratio of width D to width W of second type region 126 can be less than 0.1.

Referring to FIGS. 1A and 1B, a porous metal 114 can be disposed on the bottom surface of heat spreader structure 110. In some embodiments, porous metal 114 can be mounted on the bottom surface of heat spreader structure 110 by a sintering process. In some embodiments, porous metal 114 can be disposed between metal TIM 134 and memory TIMs 136, or between SoC die 104 and memory dies 106, or between first type region 124 and second type regions 126. In some embodiments, porous metal 114 can partially or totally enclose metal TIM 134, as shown in FIG. 1A. In some embodiments, porous metal 114 can partially or totally enclose first type region 124, as shown in FIG. 1B. In some embodiments, porous metal 114 can include pores, which can absorb an overflow of metal TIM 134 during the reflow treatment on metal TIM 134, avoiding a contamination of the overflow of metal TIM 134 in regions beyond first type region 124. In some embodiments, during the reflow treatment, the pores of porous metal 114 can facilitate a flux vapor released by metal TIM 134 to pass through and to be exhausted via perforated channels 116. In some embodiments, a porosity of porous metal 114 can be between about 1% and about 70%. For example the porosity of porous metal 114 can be about 5%, about 10%, about 20%, about 30%, about 40%, about 50%, about 60%, and about 70%. Porous metal 114 can include metal elements or metal alloys. For example, porous metal 114 can include tungsten (W), titanium (Ti), silver (Ag), ruthenium (Ru), molybdenum (Mo), copper (Cu), cobalt (Co), aluminum (Al), iridium (Ir), nickel (Ni), and a combination thereof.

In some embodiments, porous metal 114 can have a shape conforming to the perimeter of first type region 124. For example, as shown in FIG. 1B, porous metal 114 can have a rectangular ring shape including first edges with a width d1 and second edges with a width d2. The first edges are disposed between first type region 124 and second type regions 126. In some embodiments, a ratio of width d1 to distance G can be between about 0.1 to about 1. For example, the ratio of width d1 to distance G can be about 0.1, about 0.2, about 0.3, about 0.4, about 0.5, about 0.6, about 0.7, about 0.8, about 0.9, and about 1. If the ratio of width d1 to distance G is greater than about 1, the first edges of porous metal 114 cannot fit between first type region 124 and second type regions 126, affecting the coverage of metal TIM 134 on the top surface of SoC die 104 and/or the coverage of memory TIMs 136 on top surfaces of memory dies 106. If the ratio of width d1 to distance G is less than about 0.1, width d1 may be too small to sufficiently absorb the overflow of metal TIM 134 during the reflow treatment.

Referring to FIG. 1A, porous metal 114 can have a thickness h. In some embodiments, a ratio of thickness h to thickness C of metal TIM 134 can be between about 0.1 and about 1. For example, the ratio of thickness h to thickness C can be about 0.1, about 0.2, about 0.3, about 0.4, about 0.5, about 0.6, about 0.7, about 0.8, about 0.9, and about 1. If the ratio of thickness h to thickness C is greater than about 1, there may be a potential risk that porous metal 114 is in contact with the IC dies due to misalignment and/or vibration, impacting the functionalities of the IC dies. If the ratio of thickness h to thickness C is less than about 0.1, thickness h may be too small to sufficiently absorb the overflow of metal TIM 134 during the reflow treatment.

In some embodiments, heat spreader structure 110 can include groove structures 118 disposed at the bottom surface of heat spreader structure 110 and connecting to perforated channels 116, as shown in FIGS. 1A and 1B. Groove structures 118 can be disposed within second type regions 126 and aligned with the top surfaces of memory dies 106. Memory TIMs 136, when injected through perforated channels 116, can be distributed by a capillary force along groove structures 118 and dispensed on the top surfaces of memory dies 106. Groove structures 118 can include multiple grooves extending in a radiative pattern from each of the perforated channels 116. For example, as shown in FIG. 1B, each perforated channel 116 can be connected to eight grooves extending from a perimeter of perforated channel 116 to edges and corners of second type region 126. An angle θ between adjacent grooves can be determined by width W and length L as arctan (W/L) or arctan (L/W). For example, angle θ can be about 45° if second type region 126 has a square shape. Each of the grooves can have a width Q, as shown in FIG. 1B. In some embodiments, a ratio of width Q to width W of second type region 126 can be between about 0.01 and about 0.1. Each of the grooves can have a depth S measured between the bottom surface of heat spreader structure 110 and a bottom of groove structures 118, as shown in FIG. 1A. In some embodiments, a ratio of depth S and to thickness H of heat spreader structure 110 can be between about 0.1 and about 0.5. If the ratio of width Q to width W is less than about 0.01 and/or if ratio of depth S and to thickness H is less than about 0.1, cross sections of the grooves may be too small to efficiently distribute memory TIMs 136 to edges of second type regions 126. If the ratio of width Q to width W is greater than about 0.1, and/or if ratio of depth S and to thickness H is greater than 0.5, cross sections of the grooves may be too large to provide sufficient capillary force to drive memory TIMs 136 to edges and/or corners of second type region 126. In some embodiments, the cross section of the grooves can have a rectangular shape, a triangular shape, a curved shape, a half circle shape, an arched shape, or an irregular shape.

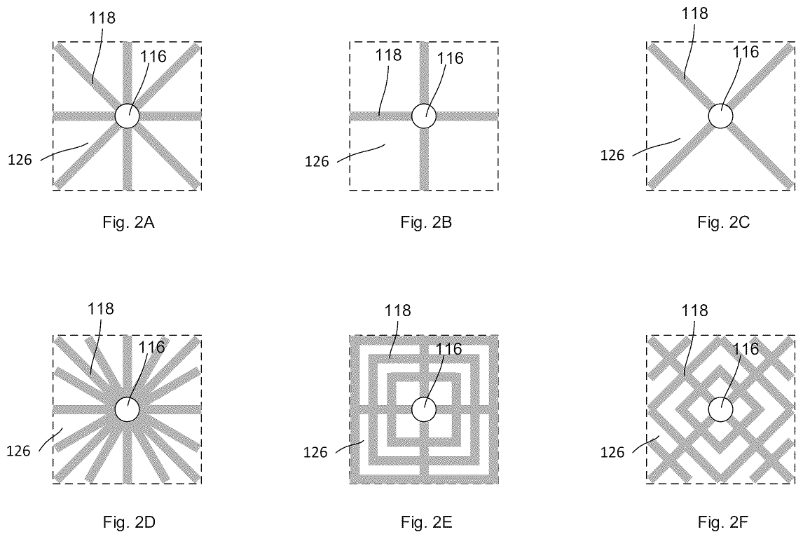

Referring to FIGS. 2A-2F, in some embodiments, groove structures 118 can have different patterns. The description of groove structure 118 above applies to FIGS. 2A-2F, unless mentioned otherwise. FIG. 2A shows groove structure 118 having the same pattern as in FIG. 1B. FIG. 2B shows groove structure 118 having four grooves extending from the perimeter of perforated channel 116 to the edges of second type region 126, with the four grooves parallel to the edges, and an angle between neighboring grooves at about 90°. FIG. 2C shows groove structure 118 having four grooves extending from the perimeter of perforated channel 116 to the corners of second type region 126, with the four grooves along diagonals of second type region 126, and an angle between neighboring grooves at about 90°. FIG. 2D shows groove structure 118 having sixteen grooves extending from the perimeter of perforated channel 116 to the corners and edges of second type region 126, with an angle between neighboring grooves at about 22.5°. FIG. 2E shows that, in addition to the pattern shown in FIG. 2B, groove structure 118 can further include some grooves crossing the four grooves extending from the perimeter of perforated channel 116 to the edges of second type region 126 and some grooves at a peripheral of second type region 126. FIG. 2F shows that, in addition to the pattern shown in FIG. 2C, groove structure 118 can further include some grooves crossing the four grooves extending from the perimeter of perforated channel 116 to the corners of second type region 126.

In some embodiments, all groove structures 118 of heat spreader structure 110 can have the same pattern of any one among FIGS. 2A-2F. In some embodiments, different groove structures 118 of heat spreader structure 110 can have different patterns among FIGS. 2A-2F.

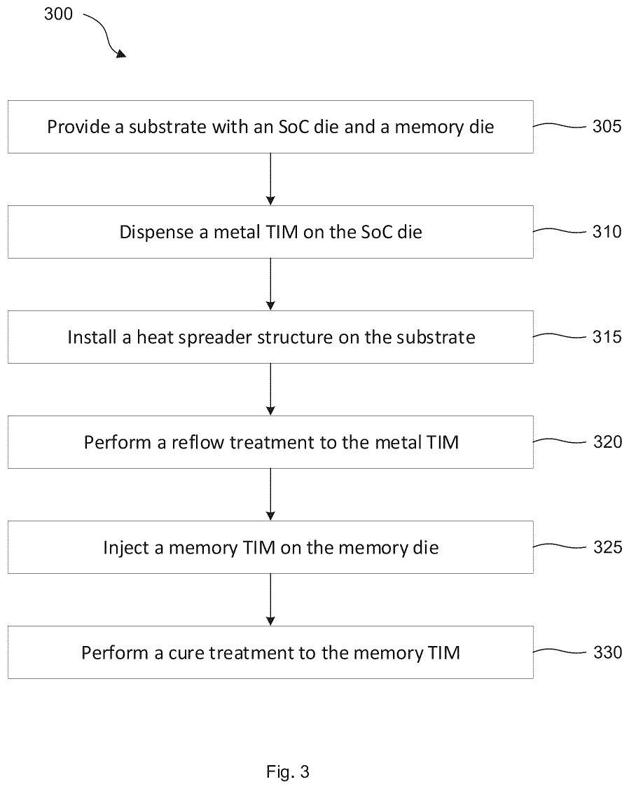

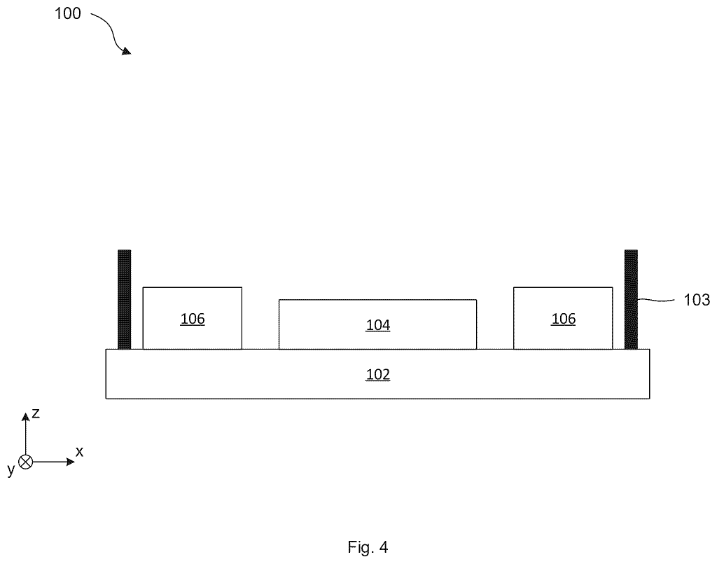

According to some embodiments, FIG. 3 illustrates a flowchart of a method 300 for forming structure 100 as shown in FIGS. 1A and 1B. This disclosure is not limited to this operational description and additional operations may be performed. Other operations can be performed between the various operations of method 300 and are omitted merely for clarity. Moreover, not all operations may be needed to perform the disclosure provided herein. Additionally, some of the operations may be performed simultaneously, or in a different order than the ones shown in FIG. 3. In some embodiments, one or more other operations may be performed in addition to or in place of the presently described operations. For illustrative purposes, method 300 is described with reference to intermediate structures shown in FIGS. 4-8. The discussion of elements in FIGS. 1A and 1B with the same annotations applies to FIGS. 4-8, unless mentioned otherwise.

Referring to FIG. 3, method 300 begins with operation 305, in which structure 100 is provided, as described with reference to FIG. 4. Structure 100 at this stage of method 300 can include substrate 102 and multiple IC dies on substrate 102. For example, as shown in FIG. 4, structure 100 can include a first IC die, such as SoC die 104, a second and third IC dies, such as memory dies 106 disposed on first and second sides adjacent to SoC die 104, respectively. Structure 100 can also include supporting structures 103 disposed on substrate 102 to provide support to heat spreader structure 110 installed in subsequent operations.

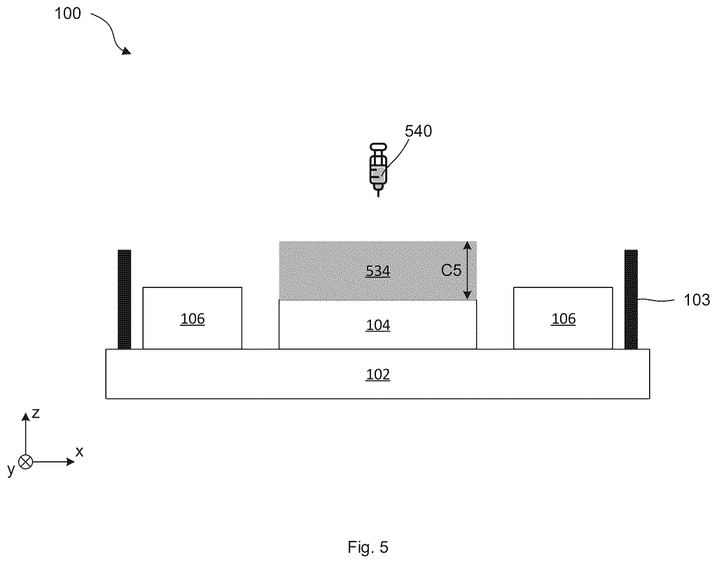

Referring to FIG. 3, method 300 continues with operation 310 and the process of dispensing a first TIM on the first IC die, as described with reference to FIG. 5. In some embodiments, the first TIM can be a metal TIM 534, as shown in FIG. 5. In some embodiments, metal TIM 534 can be in a form of liquid, grease, or epoxy originally stored in a syringe 540 before dispensed on SoC die 104. In some embodiments, a volume of metal TIM 534 dispensed on SoC die 104 can be controlled such that metal TIM 534 can cover an entirety of the top surface of SoC die 104, as shown in FIG. 5. In some embodiments, the volume of metal TIM 534 dispensed on SoC die 104 can be controlled such that metal TIM 534 can partially cover the top surface (e.g., a central region of the top surface) of SoC die 104. The volume of metal TIM 534 dispensed on SoC die 104 can be controlled so that metal TIM 534 can have a thickness C5, as shown in FIG. 5.

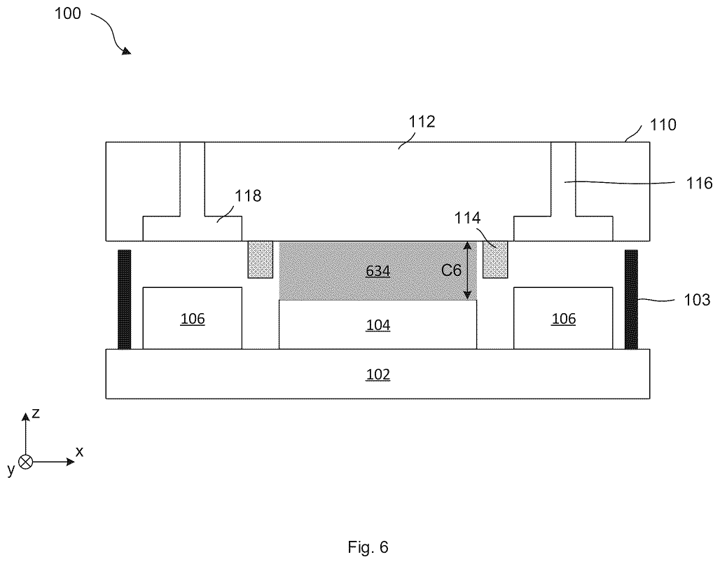

Referring to FIG. 3, method 300 continues with operation 315 and the process of installing a heat spreader structure on the substrate, as described with reference to FIG. 6. For example, heat spreader structure 110 can be placed or mounted over SoC die 104 and memory dies 106. In some embodiments, because of the presence of heat spreader structure 110, the first TIM can be deformed. For example, metal TIM 534 can be deformed into a metal TIM 634 with a thickness C6 different from C5. In some embodiments, due to its liquid, grease, or epoxy form, metal TIM 634 can physically fill a space (e.g., a gap) between the bottom surface of heat spreader structure 110 and the top surface of SoC die 104. In some embodiments, because of the presence of metal TIM 634, heat spreader structure 110 may not touch supporting structures 103. In some embodiments, heat spreader structure 110 may touch supporting structures 103. In some embodiments, installing heat spreader structure 110 can include aligning heat spreader structure 110 with SoC die 104, such that metal TIM 634 is surrounded or enclosed by porous metal 114 on the bottom surface of heat spreader structure 110. In some embodiments, installing heat spreader structure 110 can include aligning heat spreader structure 110 with memory dies 106, such that perforated channels 116 in heat spreader structure 110 are positioned above memory dies 106 (e.g., above the central regions of memory dies 106). In some embodiments, installing heat spreader structure 110 can include aligning heat spreader structure 110 with memory dies 106, such that groove structures 118 of heat spreader structure 110 are positioned above memory dies 106.

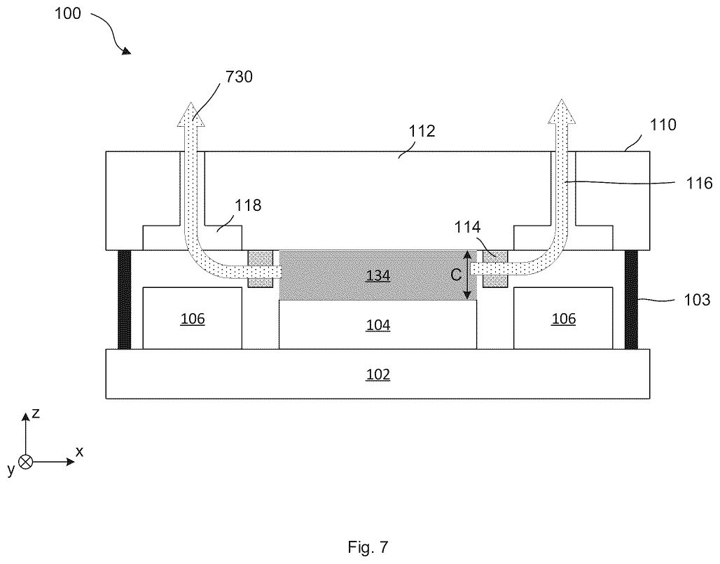

Method 300 continues with operation 320 to perform a reflow treatment to the first metal TIM, as described with reference to FIG. 7. The reflow treatment can be a thermal reflow process, in which structure 100 at this stage can be heated an elevated temperature, so that metal TIM 634 in FIG. 6 can be softened and be further reshaped into metal TIM 134 in FIG. 7 to form mechanical bonds with SoC die 104 and heat spreader structure 110. The mechanical bonds can ensure reliable thermal contacts between metal TIM 134 and SoC die 104 and between metal TIM 134 and heat spreader structure 110. In some embodiments, the reflow treatment can be performed by placing structure 100 as shown in FIG. 7 into an oven or furnace with ventilation. In some embodiments, during the reflow treatment, due to the elevated temperature, metal TIM 134 can release a flux vapor 730, which can flow through porous metal 114 and can be exhausted through perforated channels 116. In some embodiments, the presence of perforated channels 116 in heat spreader structure 110 can facilitate the release of flux vapor 730 outside structure 100, avoiding its condensation and contamination on the surfaces within structure 100. In some embodiments, the reflow treatment can cause a reduction of the volume of metal TIM 134 (e.g., due to the release of flux vapor 730). Being supported by metal TIM 134, heat spreader structure 110 can sink accordingly to conform the reduction of the volume of metal TIM 134, so that metal TIM 134 can maintain sufficient coverage on the top surface of SoC die 104 without shrinking towards the central region of SoC die 104 or creating bubbles at interfaces between metal TIM 134 and SoC die 104 or between metal TIM 134 and heat spreader structure 110. In some embodiments, after the reflow treatment, thickness C of metal TIM 134 is less than thickness C6 of metal TIM 634 as shown in FIG. 6. In some embodiments, after the reflow treatment, heat spreader structure 110 may sink and be in contact with supporting structures 103. In some embodiments, a corner thermal resistivity R_{jc} of metal TIM 134 can be maintained substantially the same as before the reflow treatment. For example, the corner thermal resistivity R_{jc} can be maintained to be less than about 0.25° C./W. In some embodiments, during the reflow treatment, porous metal 114 can absorb an overflow of metal TIM 134 over the edge of SoC die 104, guarding metal TIM 134 within the range of the top surface of the SoC die 104 and avoiding its contamination to other parts of structure 100.

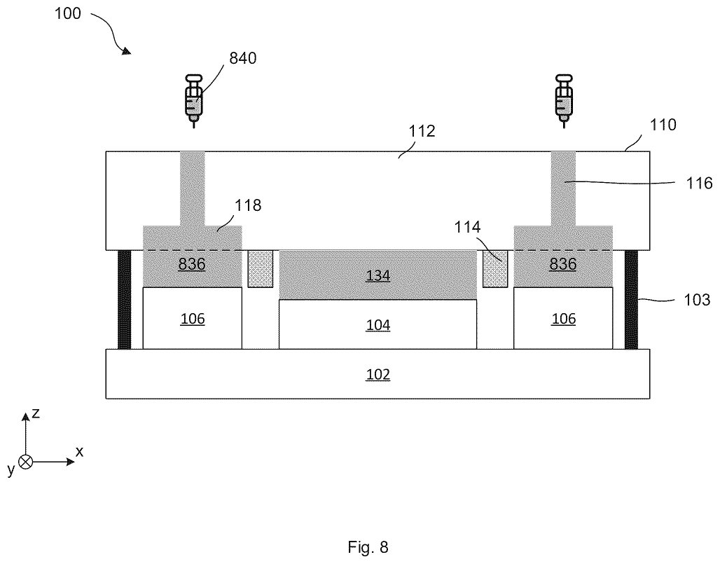

In referring to FIG. 3, method 300 continues with operation 325 and the process of injecting a second TIM on the second and/or third dies, as described with reference to FIG. 8. In some embodiments, the second TIM can be a memory TIM 836, as shown in FIG. 8. In some embodiments, memory TIM 836 can be in a form of liquid, grease, or epoxy stored in syringes 840 before dispensed on memory dies 106. Memory TIM 836 can be injected through perforated channels 116 and flow along groove structures 118 to be evenly spread and delivered on top surfaces of memory dies 106. In some embodiments, a volume of memory TIM 836 dispensed on memory dies 106 can be controlled such that memory TIM 836 can cover an entirety of the top surfaces of memory dies 106, as shown in FIG. 8. In some embodiments, the volume of memory TIM 836 dispensed on memory dies 106 can be controlled such that memory TIM 836 can be in contact with top surfaces of memory dies 106 and the bottom surface of heat spreader structure 110. In some embodiments, the volume of memory TIM 836 dispensed on memory dies 106 can be controlled such that memory TIM 836 can partially or entirely fill perforated channels 116. For example, as shown in FIG. 8, top surfaces of memory TIM 836 can be coplanar with a top surface of heat spreader structure 110. In some embodiments, when memory TIM 836 is being dispensed, porous metal 114 aligned between memory dies 106 and SoC die 104 can absorb an overflow of memory TIM 836 outside the top surfaces of memory dies 106 to avoid its contamination to other part (such as SoC die 104) of structure 100.

In referring to FIG. 3, method 300 continues with operation 330 and the process of a cure treatment to the second TIM. For example, the cure treatment can harden memory TIM 836 in FIG. 8 into a solid form of memory TIM 136 in FIG. 1, forming mechanical bonds with memory dies 106 and heat spreader structure 110 to ensure reliable thermal contacts. In some embodiments, the cure treatment can be performed at an elevated temperature above room temperature and for a rapid cure duration and may be referred to as a “snap cure” treatment. In some embodiments, the cure treatment on structure 100 can be performed in an oven or furnace, such as a rapid thermal treatment furnace.

The embodiments described herein are directed to a method of forming a structure of semiconductor package with a heat spreader structure for heat dissipation. The method includes dispensing a first TIM on a first IC die on a substrate, mounting the heat spreader structure on the first TIM, performing a reflow treatment on the first TIM to form a first thermal contact between the heat spreader structure and the first IC die, injecting a second TIM on a second IC die on the substrate through a perforated channel in the heat spreader structure and aligned with the second IC die, and performing a cure treatment on the second TIM to form a second thermal contact between the heat spreader structure and the second IC die. Because the reflow treatment on first TIM is formed before the second TIM is dispensed on the second IC, the first thermal contact can be formed without an interference of the second TIM. Therefore, a reduction of a coverage of the first TIM over the first IC die, hence a compromise of a quality of the first thermal contact can be avoided. Furthermore, features of the heat spreader structure can provide additional benefits to the method, including (i) a porous metal on a bottom surface of the heat spreader structure and aligned between the first and second IC dies can absorb an overflow of the first and/or second TIMs, (ii) the perforated channel can facilitate an exhaust of a flux vapor released by the first TIM during the reflow process, and (iii) a groove structure connected to the perforated channel and aligned with the second IC die can guide a flow of the second TIM to be evenly dispensed on the second IC die.

In some embodiments, a method includes providing a substrate with first and second dies on the substrate, dispensing a first TIM on the first die, and forming a heat spreader structure on the substrate. Forming the heat spreader structure includes aligning a porous metal of the heat spreader structure with the first die and forming a contact between the first TIM and the heat spreader structure. The method further includes performing a reflow treatment on the first TIM, injecting a second TIM on the second die through a perforated channel in the heat spreader structure, and performing a cure treatment to the second TIM.

In some embodiments, a method includes providing, on a substrate, first and second dies separated by a distance, dispensing a TIM on the first die, mounting a heat spreader structure on the first and second dies with a porous metal of the heat spreader structure between the first and second dies, forming a first thermal contact between the first die and the heat spreader structure via the first TIM, injecting a second TIM on the second die through a perforated channel in the heat spreader structure, and forming a second thermal contact between the second die and the heat spreader structure via the second TIM.

In some embodiments, a structure includes first and second dies on a substrate and a heat spreader structure on the substrate. The heat spreader structure includes a porous metal surrounding the first die and a perforated channel above the second die. The structure further includes a first TIM and a second TIM. The first TIM is in contact with the first die and the heat spreader structure. The second TIM is in contact with the second die and through the perforated channel.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a substrate, wherein the substrate comprises first and second dies on the substrate;
dispensing a first thermal interface material (TIM) on the first die;
forming a heat spreader structure on the substrate, wherein forming the heat spreader structure comprises:
aligning a porous metal of the heat spreader structure with the first die; and
forming a contact between the first TIM and the heat spreader structure;
performing a reflow treatment on the first TIM;
injecting a second TIM on the second die through a perforated channel in the heat spreader structure; and
performing a cure treatment to the second TIM.

2. The method of claim 1, wherein forming the heat spreader structure further comprises aligning the perforated channel with the second die.

3. The method of claim 1, wherein forming the heat spreader structure further comprises aligning a groove structure of the heat spreader structure with the second die, wherein the groove structure and the perforated channel are connected.

4. The method of claim 1, wherein aligning the porous metal of the heat spreader structure with the first die comprises enclosing the first TIM by the porous metal.

5. The method of claim 1, wherein performing the reflow treatment comprises exhausting a flux vapor released by the first TIM through the perforated channel.

6. The method of claim 1, wherein performing the reflow treatment comprises using the porous metal to absorb an overflow of the first TIM away from the first die.

7. The method of claim 1, wherein injecting the second TIM comprises injecting the second TIM after performing the reflow treatment.

8. The method of claim 1, wherein injecting the second TIM comprises spreading the second TIM along a groove structure of the heat spreader structure.

9. A method, comprising:
providing, on a substrate, first and second dies separated by a distance;
dispensing a first thermal interface material (TIM) on the first die;
mounting a heat spreader structure on the first and second dies, wherein a porous metal of the heat spreader structure is between the first and second dies;
forming a first thermal contact between the first die and the heat spreader structure via the first TIM;
injecting a second TIM on the second die through a perforated channel in the heat spreader structure; and
forming a second thermal contact between the second die and the heat spreader structure via the second TIM.

10. The method of claim 9, wherein forming the first thermal contact comprises performing a reflow treatment.

11. The method of claim 9, wherein forming the first thermal contact comprises maintaining a coverage of the first TIM over a top surface of the first die.

12. The method of claim 9, wherein forming the first thermal contact comprises reducing a thickness of the first TIM.

13. The method of claim 9, wherein forming the first thermal contact comprises maintaining a corner thermal resistance of the first TIM to be less than 0.25° C./W.

14. The method of claim 9, wherein injecting the second TIM delivering the second TIM through a groove structure of the heat spreader structure, wherein the groove structure is connected to the perforated channel and above the second die.

15. The method of claim 9, wherein forming the second thermal contact comprises performing a cure treatment.

16. A structure, comprising:
first and second dies on a substrate;
a heat spreader structure on the substrate, wherein the heat spreader structure comprises:
a porous metal surrounding the first die; and
a perforated channel above the second die;
a first thermal interface material (TIM) in contact with the first die and the heat spreader structure; and
a second TIM in contact with the second die and through the perforated channel.

17. The structure of claim 16, wherein a coverage of the first TIM over the first die is greater than about 90%.

18. The structure of claim 16, wherein a corner thermal resistance of the first TIM is less than about 0.25° C./W.

19. The structure of claim 16, further comprising a groove structure above the second die and connected to the perforated channel.

20. The structure of claim 19, wherein a ratio of a depth of the groove structure to a thickness of the heat spreader structure is between about 0.1 and about 0.5.
